(19) United States
(12) Patent Application Publication
(10) Pub. No.: US 2014/0192592 A1
(43) Pub. Date: Jul. 10, 2014

(54) SB-TE-TI PHASE-CHANGE MEMORY MATERIAL AND TI-SB2TE3 PHASE-CHANGE MEMORY MATERIAL

(71) Applicant: SHANGHAI INSTITUTE OF MICROSYSTEM AND INFORMATION TECHNOLOGY, CHINESE ACADAMY OF SCIENCES, Shanghai (CN)

(72) Inventors: Liangcai Wu, Shanghai (CN); Min Zhu, Shanghai (CN); Zhitang Song, Shanghai (CN); Feng Rao, Shanghai (CN); Cheng Peng, Shanghai (CN); Xilin Zhou, Shanghai (CN); Kun Ren, Shanghai (CN); Songlin Feng, Shanghai (CN)

(73) Assignee: Shanghai Institute of Microsystem and Information Technology Chinese Academy, Shanghai (CN)

(21) Appl. No.: 13/885,894

(22) PCT Filed: Dec. 26, 2012
(86) PCT No.: PCT/CN2012/087572

§ 371 Date: May 16, 2013

(30) Foreign Application Priority Data
Mar. 21, 2012 (CN) 201210076491.9

(51) Int. Cl. G11C 13/00; C23C 14/34

(52) U.S. Cl. CPC G11C 13/0004; C23C 14/3414
USPC 365/163; 252/519.12; 204/192.15

(57) ABSTRACT

The present invention relates to an Sb—Te—Ti phase-change thin-film material applicable to a phase-change memory and preparation thereof. The Sb—Te—Ti phase-change memory material of the present invention is formed by doping an Sb—Te phase-change material with Ti, Ti forms bonds with both Sb and Te, and the Sb—Te—Ti phase-change memory material has a chemical formula SbₓTe_{y}Ti_{100-x-y}, where 0<x<80 and 0<y<100-x. When the Sb—Te—Ti phase-change memory material is a Ti—Sb₂Te₃ phase-change memory material, Ti atoms replace Sb atoms, and phase separation does not occur. In a crystallization process of an Sb—Te phase-change material in the prior art, gain growth dominates, so the phase change rate is high, but the retention cannot meet industrial requirements.

### BACKGROUND OF THE PRESENT INVENTION

1. Field of Invention

The present invention relates to a phase-change material and a preparation method thereof, and more particularly to an Sb—Te—Ti phase-change thin-film material applicable to a phase-change memory.

2. Description of Related Arts

Phase-change memory (or Phase Change Random Access Memory, PCRAM for short) use phase change materials, i.e. chalcogenide compounds as storage medium, which may be electrically switched between a generally crystalline state (relatively lower resistance) and a generally amorphous state (relatively higher resistance) by utilizing electric energy (heat) for electronic memory application in order to write and erase information. Information read is relied on the measured resistance, in which whether it is a higher resistance representing “1” or a lower resistance representing “0” is determined.

Grain growth dominates during a crystallization process of Sb—Te based phase-change materials, resulting in a high phase-change rate and a lower melting point than that of Ge₂Sb₂Te₅ (GST). As a result, less power is consumed. However, the Sb—Te based phase-change materials have such disadvantages as a low crystallization temperature, poor thermal stability, and poor data retention.

An Sb₂Te₃ phase-change material has a very high crystallization rate, and meanwhile a low melting point. However, Sb₂Te₃ has a very low crystallization temperature, and a very poor thermal stability. For consumer electronics, a non-volatile memory is required to store data for at least 10 years under the condition of 85° C., and even stricter requirements exist in industrial electronics. Without being doped, the Sb₂Te₃ phase-change material cannot be applied to a phase-change memory.

In the present invention, the Sb₂Te₃ phase-change material is doped with Ti to significantly rise the crystallization temperature, so as to improve the data retention, thereby satisfying practical requirements.

### SUMMARY OF THE PRESENT INVENTION

An objective of the present invention is to provide an Sb—Te—Ti phase-change material for a phase-change memory, so as to improve the thermal stability and increase the amorphous state resistance of the phase-change material, and reduce a Reset current and the melting temperature of the material.

The present invention further provides a Ti—Sb₂Te₃ phase-change memory material with Ti doped, which is used for a phase-change memory, so as to improve the thermal stability and increase the amorphous state resistance. Meanwhile, after being doped with Ti, gains become smaller, and phase separation does not occur. The melting point and the thermal conductivity of the Ti—Sb₂Te₃ phase-change memory material doped with Ti are both lower than before. In a phase-change memory based on this phase-change material, as the content of Ti increases, the high resistance increases firstly and then decreases, and the high-resistance-to-low-resistance ratio also increases at first and then decreases.

In order to solve the above technical problems, the present invention is implemented by adopting the following technical solutions.

An Sb—Te—Ti phase-change memory material for a phase-change memory is provided, which is formed by doping an Sb—Te phase-change material with Ti, and has a chemical formula SbₓTe_{y}Ti_{100-x-y}, where 0<x<80, and 0<y<100-x. In the chemical formula of the present invention, right subscripts represent the molar ratio.

Preferably, x satisfies 45≦x≦72, and y satisfies 5≦y≦45.

In the Sb—Te—Ti phase-change memory material, doped Ti forms chemical bonds with both Sb and Te.

Preferably, the Sb—Te—Ti phase-change memory material is an Sb—Te—Ti phase-change thin-film material. Preferably, the thickness of the Sb—Te—Ti phase-change thin-film material is in the range of 100 to 250 nm.

Preferably, the resistivity of the Sb—Te—Ti phase-change memory material is reversibly changed under the action of an electric pulse.

Preferably, the optical reflectivity of the Sb—Te—Ti phase-change memory material is reversibly changed under the action of a laser pulse.

The crystallization temperature of the Sb—Te—Ti phase-change memory material is significantly risen, the thermal stability and the data retention are both improved.

The amorphous state resistance of the Sb—Te—Ti phase-change memory material is decreased, and the crystalline state resistance is increased.

In the Sb—Te—Ti phase-change memory material for a phase-change memory according to the present invention, the Sb—Te phase-change memory material is an Sb₂Te₃ phase-change memory material, the Sb—Te—Ti phase-change memory material obtained by doping the Sb₂Te₃ phase-change memory material with Ti is a Ti—Sb₂Te₃ phase-change memory material with the chemical formula SbₓTe_{y}Ti_{100-x-y},

$$y = \frac{3}{2} x ,$$

and the Ti atom percentage content is lower than 50%.

Preferably, in the Ti—Sb₂Te₃ phase-change memory material, the percentage content of Ti is in the range of 2% and 20%.

Preferably, in the Ti—Sb₂Te₃ phase-change memory material, Ti atoms replace Sb atoms, and phase separation does not occur.

Preferably, the resistivity of the Ti—Sb₂Te₃ phase-change memory material is reversibly changed under the action of an electric pulse.

Preferably, the optical reflectivity of the Ti—Sb₂Te₃ phase-change memory material is reversibly changed under the action of a laser pulse.

Preferably, in the Ti—Sb₂Te₃ phase-change memory material, as the content of doped Ti increases, the amorphous state resistance of the Ti—Sb₂Te₃ phase-change memory material increases and then decreases.

Preferably, the crystallization temperature of the Ti—Sb₂Te₃ phase-change memory material is significantly risen, and the thermal stability and the data retention are improved.

Preferably, gains of the Ti—Sb₂Te₃ phase-change memory material are smaller (compared with grains of Sb₂Te₃), and phase separation does not occur.

Preferably, the melting point and the thermal conductivity of the Ti—Sb₂Te₃ phase-change memory material are lowered.

A preparation method of an Sb—Te—Ti phase-change memory material according to the present invention includes the following steps.

According to a ratio of Sb to Te in a chemical formula SbₓTe_{y}Ti_{100-x-y}, an SbₓTe_{y} alloy target and a Ti target are co-sputtered to obtain the Sb—Te—Ti phase-change memory material.

Preferably, sputtering conditions of the co-sputtering are: in the process of co-sputtering, an Ar gas with a purity of 99.999% is fed at the same time, the SbₓTe_{y} target adopts a radio frequency power supply, and the Ti target adopts a direct current power supply. Preferably, the power of the radio frequency power supply is 25 W, and the power of the direct current power supply is 15 W.

Preferably, during co-sputtering, the SbₓTe_{y} alloy target is started before the Ti target power supply is turned on.

Preferably, the co-sputtering duration is 15 minutes to 50 minutes.

The obtained Sb—Te—Ti phase-change memory material is a phase-change thin-film material, and the thickness of the film is in the range of 100 nm to 250 nm.

A sputtering device used in the present invention is a conventional sputtering device in the prior art.

The present invention further provides a phase-change memory unit based on an Sb—Te—Ti phase-change memory material.

Preferably, the Sb—Te—Ti phase-change memory material is a Ti—Sb₂Te₃ phase-change material doped with Ti.

Preferably, in the phase-change memory unit based on the Ti—Sb₂Te₃ phase-change material doped with Ti, after being doped with Ti, grains of the Sb₂Te₃ phase-change memory material become smaller, so the adhesion of the Ti—Sb₂Te₃ phase-change memory material to upper and lower electrodes increases.

Preferably, in the phase-change memory unit based on the Ti—Sb₂Te₃ phase-change material doped with Ti, as the content of the doped Ti increases, a Reset voltage of the phase-change memory unit increases.

Preferably, in the phase-change memory unit based on the Ti—Sb₂Te₃ phase-change material doped with Ti, as the content of the doped Ti increases, the high resistance and the low resistance of the phase-change memory unit are more stable.

Preferably, in the phase-change memory unit based on the Ti—Sb₂Te₃ phase-change material doped with Ti, as the content of the doped Ti increases, the high resistance of the phase-change memory unit increases and then decreases, and similarly, the high-resistance-to-low-resistance ratio also increases and then decreases.

Preferably, the high-resistance-to-low-resistance ratio of the phase-change memory unit based on the Ti—Sb₂Te₃ phase-change material doped with Ti is greater than an order of magnitude.

Preferably, the phase-change memory unit based on the Ti—Sb₂Te₃ phase-change material doped with Ti has a very high Set operation speed (on the order of nanosecond).

Preferably, the phase-change memory unit based on the Ti—Sb₂Te₃ phase-change material doped with Ti has a great number of repeated operations.

Beneficial effects of the present invention are as follows.

According to the present invention, the Sb—Te phase-change memory material is doped with Ti, Ti forms bonds with both Sb and Te, and the crystallization temperature Sb—Te—Ti phase-change memory material obtained by doping Ti is risen, the data retention is improved, and the thermal stability is enhanced. The crystalline state resistance increases, and the Reset power consumption decreases.

In the Ti—Sb₂Te₃ phase-change memory material of the present invention, Ti atoms replace Sb atoms, and phase separation does not occur; the Ti—Sb₂Te₃ phase-change memory material is evenly distributed, and the grains are small; the crystallization temperature is significantly risen, and the thermal stability and the data retention are enhanced; as the content of the doped Ti increases, the amorphous state resistance of the Ti—Sb₂Te₃ phase-change memory material increases and then decreases; the melting point and thermal conductivity are lowered.

### BRIEF DESCRIPTION OF THE DRAWINGS

FIG. 1 is a graph showing a relationship between the sheet resistance and the temperature of an Sb₆₀Te₃₀Ti₁₀ film at different heating rates.

FIG. 2 shows the retention time of an Sb₆₀Te₃₀Ti₁₀ film at different temperatures in Embodiment 1.

FIG. 3 shows the crystallization activation energy and a 10-year retention temperature of an Sb₆₀Te₃₀Ti₁₀ film in Embodiment 1.

FIG. 4 shows a voltage-resistance curve of a phase-change device unit based on the Sb₆₀Te₃₀Ti₁₀ film in Embodiment 1.

FIG. 5 shows sheet-resistance-temperature curves of Sb₂Te₃ and three Ti—Sb₂Te₃ films having different contents of Ti at a heating rate of 10° C./min in Embodiment 6.

FIG. 6 shows an X-ray diffraction result of an Sb₂Te₃ and a Ti—Sb₂Te₃ film doped with 10% Ti after annealing for 5 minutes at 300° C. in Embodiment 6.

FIG. 7 shows the data retention of Ti—Sb₂Te₃ doped with 10% Ti in Embodiment 6.

FIG. 8 shows resistance-voltage curves of a phase-change memory device unit based on Ti—Sb₂Te₃ doped with 10% Ti in Embodiment 6.

### DETAILED DESCRIPTION OF THE PREFERRED EMBODIMENTS

The present invention is further illustrated below with reference to specific embodiments, and it should be understood that the embodiments are only intended to illustrate the present invention, but are not intended to limit the protection scope of the present invention.

### Embodiment 1

Preparation of an Sb₆₀Te₃₀Ti₁₀ Nanocomposite Phase-Change Material

In this embodiment, the nanocomposite phase-change material is obtained by co-sputtering an Sb₆₀Te₃₀ alloy target and a Ti target. Specific preparation conditions are: in the process of co-sputtering, an Ar gas with a purity of 99.999% is fed at the same time, the Sb₆₀Te₃₀ target adopts a radio frequency power supply, the Ti target adopts a direct current power supply, the power of the adopted radio frequency power supply is 25 W, and the power of the adopted direct current power supply is 15 W. The Sb2Te target is started before the Ti target power supply is turned on. The co-sputtering duration is 20 minutes, and the thickness of a film is about 170 nm.

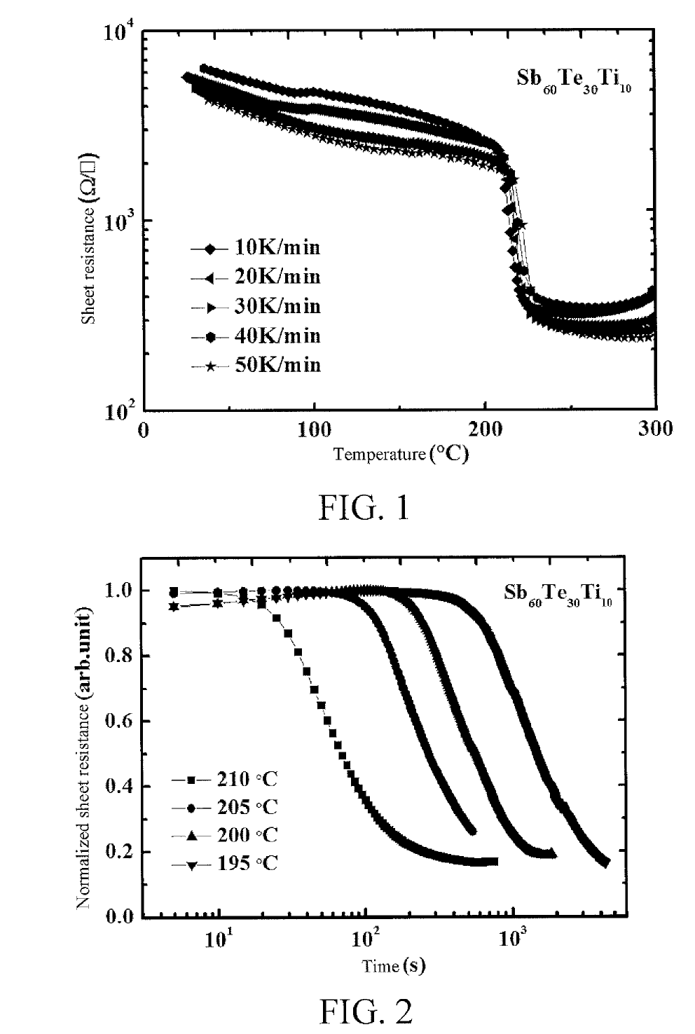

Tests of the Sb₆₀Te₃₀Ti₁₀ nanocomposite phase-change material obtained in this embodiment are performed, and results are shown in FIG. 1 to FIG. 3.

FIG. 1 is a graph showing a relationship between the Sb₆₀Te₃₀Ti₁₀ sheet resistance and the temperature at different heating rates. The applied heating rate is in the range of 10° C./min to 50° C./min. The crystallization temperature of the pure Sb₆₀Te₃₀ at the heating rate of 10° C./min is about 130° C.; after being doped with Ti, the crystallization temperature is about 212° C., which is higher than the initial crystallization temperature by 80° C. and more. The higher the heating rate is, the higher the crystallization temperature is, because when the heating rate is high, atoms do not have enough time to diffuse, and the time for crystallization gets longer.

FIG. 2 is a graph showing the retention time of the Sb₆₀Te₃₀Ti₁₀ film at different temperatures. The retention is a critical property of the phase-change material, and is an important parameter for determining whether the phase-change material can be directly applied. It can be seen from the above discussion that the crystallization temperature of Sb₆₀Te₃₀Tiₘ is 212° C., and test temperature points of retention are 195° C., 200° C., 205° C., and 210° C. respectively, as shown in FIG. 2. The reason is that the test temperature point of the retention needs to be lower than the crystallization temperature. The retention is used to characterize the thermal stability in the amorphous state. When the test temperature point is higher than the crystallization temperature, the phase-change material has been crystallized in the process of heating, so that the retention time of the amorphous state cannot be measured. Herein, the failure time is defined as time required for the resistance of the film to decrease to half of the initial resistance when the temperature just rises to the test temperature point. According to the test, the failure time corresponding to 195° C., 200° C., 205° C., and 210° C. is 1,560 s, 610 s, 275 s, and 70 s respectively, that is, the lower the temperature is, the longer the failure time is.

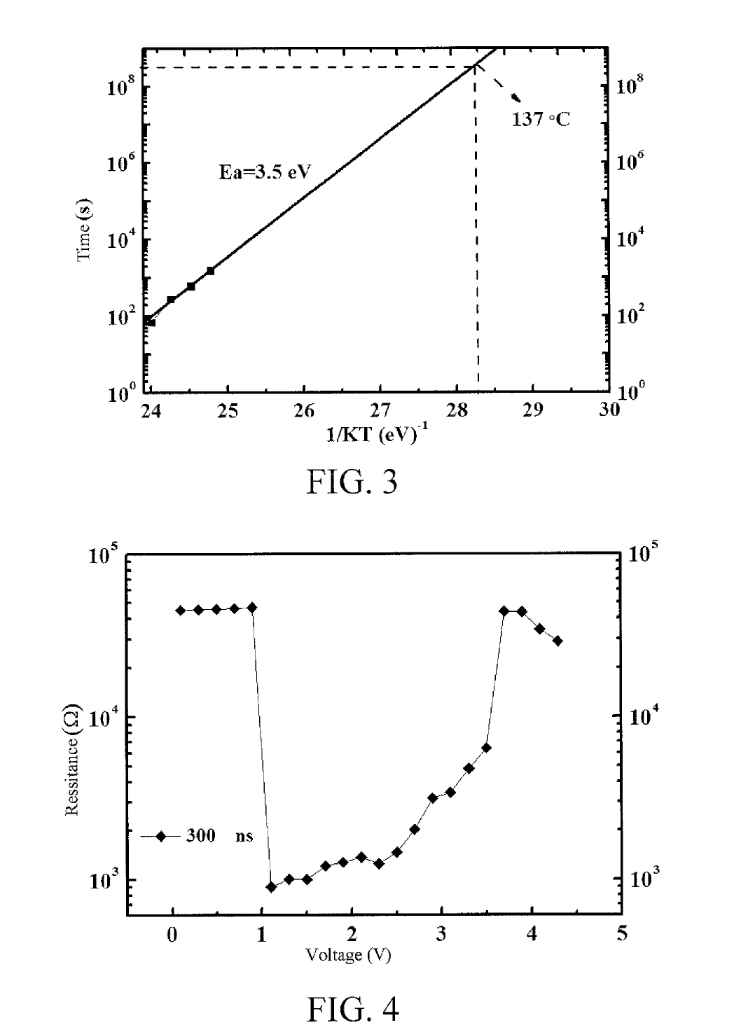

In FIG. 3, according to the Arrhenius equation, it can be deduced that the temperature corresponding to the retention time is 137° C., which is 52° C. higher than that of GST (85° C.). Automotive electronics require 10 years of retention at 120° C., so that a phase-change memory based on the Sb₆₀Te₃₀Ti₁₀ phase-change material can meet the requirement. At the time of obtaining the 10-year retention temperature, the crystallization activation energy of Sb₆₀Te₃₀Ti₁₀ may also be obtained. The crystallization activation energy of Sb₆₀Te₃₀Ti₁₀ is 3.5 ev, which is 1.2 ev higher than that of GST (2.3 ev). The increase of the crystallization activation energy improves the thermal stability in the amorphous state.

FIG. 4 shows a voltage-resistance curve of a phase-change device unit based on the Sb₆₀Te₃₀Ti₁₀ film in Embodiment 1. A voltage pulse used for testing is 300 ns, and a falling edge of the pulse is 30 ns. It can be known from FIG. 4, a voltage required for transition from the amorphous state to the polycrystalline state is 1.1 V, and a voltage required for transition from the crystalline state to the amorphous state is 3.5 V. Therefore, the Sb₆₀Te₃₀Ti₁₀ nanocomposite phase-change material of this embodiment can undergo reversible phase change under the action of the voltage pulse.

When the Sb₆₀Te₃₀Ti₁₀ nanocomposite phase-change material of this embodiment is heated by a pulsed laser, the structure may reversibly change between the amorphous state and the polycrystalline state, thereby realizing reversible change of optical reflectivity.

### Embodiment 2

Preparation of an Sb₇₂Te₁₈Ti₁₀ Nanocomposite Phase-Change Material

In this embodiment, the nanocomposite phase-change material is obtained by co-sputtering an Sb₇₂Te₁₈ alloy target and a Ti target. Specific preparation conditions are: in the process of co-sputtering, an Ar gas with a purity of 99.999% is fed at the same time, the Sb₇₂Te₁₈ target adopts a radio frequency power supply, the Ti target adopts a direct current power supply, the power of the adopted radio frequency power supply is 25 W, and the power of the adopted direct current power supply is 15 W. The Sb₇₂Te₁₈ target is started before the Ti target power supply is turned on. The co-sputtering duration is 30 minutes, and the thickness of a film is about 200 nm.

Tests of the Sb₇₂Te₁₈Ti₁₀ nanocomposite phase-change material obtained in this embodiment are performed, and results are as follows.

It can be known from a graph showing a relationship between the Sb80Te10Ti₁₀ sheet resistance and the temperature of the obtained Sb₇₂Te₁₈Ti₁₀ nanocomposite phase-change material at different heating rates that, the higher the heating rate is, the higher the crystallization temperature is.

The lower the test temperature of the obtained Sb₇₂Te₁₈Ti₁₀ nanocomposite phase-change material is, the longer the failure time is.

The obtained Sb₇₂Te₁₈Ti₁₀ nanocomposite phase-change material has a 10-year retention temperature, and while the 10-year retention temperature is obtained, the crystallization activation energy of Sb₇₂Te₁₈Ti₁₀ is much higher than that of GST (2.3 ev). The increase of the crystallization activation energy improves the thermal stability in the amorphous state.

The obtained Sb₇₂Te₁₈Ti₁₀ nanocomposite phase-change material can undergo reversible phase change under action of a voltage pulse; when being heated by a pulsed laser, the structure can reversibly change between the amorphous state and the polycrystalline state, thereby realizing reversible change of optical reflectivity.

### Embodiment 3

Preparation of an Sb₅₀Te₃₀Ti₂₀ Nnanocomposite Phase-Change Material

In this embodiment, the nanocomposite phase-change material is obtained by co-sputtering an Sb₅₀Te₃₀ alloy target and a Ti target. Specific preparation conditions are: in the process of co-sputtering, an Ar gas with a purity of 99.999% is fed at the same time, the Sb₅₀Te₃₀ target adopts a radio frequency power supply, the Ti target adopts a direct current power supply, the power of the adopted radio frequency power supply is 25 W, and the power of the adopted direct current power supply is 15 W. The Sb2Te target is started before the Ti target power supply is turned on. The co-sputtering duration is 50 minutes, and the thickness of a film is about 250 nm.

Tests of the Sb₅₀Te₃₀Ti₂₀ nanocomposite phase-change material obtained in this embodiment are performed, and results are as follows.

It can be known from a graph showing a relationship between Sb₅₀Te₃₀Ti₂₀ sheet resistance and the temperature of the obtained Sb₅₀Te₃₀Ti₂₀ nanocomposite phase-change material at different heating rates that, the higher the heating rate is, the higher the crystallization temperature is.

The lower the test temperature of the obtained Sb₅₀Te₃₀Ti₂₀ nanocomposite phase-change material is, the longer the failure time is.

The obtained Sb₅₀Te₃₀Ti₂₀ nanocomposite phase-change material has a 10-year retention temperature, and while the 10-year retention temperature is obtained, the crystallization activation energy of Sb₅₀Te₃₀Ti₂₀ is much higher than that of GST (2.3 ev). The increase of the crystallization activation energy improves the thermal stability in the amorphous state.

The obtained Sb₅₀Te₃₀Ti₂₀ nanocomposite phase-change material can undergo reversible phase change under action of a voltage pulse; when being heated by a pulsed laser, the structure can reversibly change between the amorphous state and the polycrystalline state, thereby realizing reversible change of optical reflectivity.

### Embodiment 4

Preparation of an Sb₄₅Te₄₅Ti₁₀ Nanocomposite Phase-Change Material

In this embodiment, the nanocomposite phase-change material is obtained by co-sputtering an Sb₄₅Te₄₅ alloy target and a Ti target. Specific preparation conditions are: in the process of co-sputtering, an Ar gas with a purity of 99.999% is fed at the same time, the Sb₄₅Te₄₅ target adopts a radio frequency power supply, the Ti target adopts a direct current power supply, the power of the adopted radio frequency power supply is 25 W, and the power of the adopted direct current power supply is 15 W. The Sb₄₅Te₄₅ target is started before the Ti target power supply is turned on. The co-sputtering duration is 15 minutes, and the thickness of a film is about 100 nm.

Tests of the Sb₄₅Te₄₅Ti₁₀ nanocomposite phase-change material obtained in this embodiment are performed, and results are as follows.

It can be known from a graph showing a relationship between the Sb₄₅Te₄₅Ti₁₀ sheet resistance and the temperature of the obtained Sb₄₅Te₄₅Ti₁₀ nanocomposite phase-change material at different heating rates that, the higher the heating rate is, the higher the crystallization temperature is.

The lower the test temperature of the obtained Sb₄₅Te₄₅Ti₁₀ nanocomposite phase-change material is, the longer the failure time is.

The obtained Sb₄₅Te₄₅Ti₁₀ nanocomposite phase-change material has a 10-year retention temperature, and while the 10-year retention temperature is obtained, the crystallization activation energy of Sb₄₅Te₄₅Ti₁₀ is much higher than that of GST (2.3 ev). The increase of the crystallization activation energy improves the thermal stability in the amorphous state.

The obtained Sb₄₅Te₄₅Ti₁₀ nanocomposite phase-change material can undergo reversible phase change under action of a voltage pulse; when being heated by a pulsed laser, the structure can reversibly change between the amorphous state and the polycrystalline state, thereby realizing reversible change of optical reflectivity.

### Embodiment 5

Preparation of an Sb₆₉Te₂₃Ti₈ Nanocomposite Phase-Change Material

In this embodiment, the nanocomposite phase-change material is obtained by co-sputtering an Sb₆₉Te₂₃ alloy target and a Ti target. Specific preparation conditions are: in the process of co-sputtering, an Ar gas with a purity of 99.999% is fed at the same time, the Sb₆₉Te₂₃ target adopts a radio frequency power supply, the Ti target adopts a direct current power supply, the power of the adopted radio frequency power supply is 25 W, and the power of the adopted direct current power supply is 15 W. The Sb₆₉Te₂₃ target is started before the Ti target power supply is turned on. The co-sputtering duration is 20 minutes, and the thickness of a film is about 160 nm.

Tests of the Sb₆₉Te₂₃Ti₈ nanocomposite phase-change material obtained in this embodiment are performed, and results are as follows.

It can be known from a graph showing a relationship between Sb₆₉Te₂₃Ti₈ sheet resistance and temperature of the obtained Sb₆₉Te₂₃Ti₈₅ nanocomposite phase-change material at different heating rates that, the higher the heating rate is, the higher the crystallization temperature is.

The lower the test temperature of the obtained Sb₆₉Te₂₃Ti₈ nanocomposite phase-change material is, the longer the failure time is.

The obtained Sb₆₉Te₂₃Ti₈ nanocomposite phase-change material has a 10-year retention temperature, and while the 10-year retention temperature is obtained, the crystallization activation energy of Sb₆₉Te₂₃Ti₈ is much higher than that of GST (2.3 ev). The increase of the crystallization activation energy improves the thermal stability in the amorphous state.

The obtained Sb₆₉Te₂₃Ti₈ nanocomposite phase-change material can undergo reversible phase change under action of a voltage pulse; when being heated by a pulsed laser, the structure may reversibly change between the amorphous state and the polycrystalline state, thereby realizing reversible change of optical reflectivity.

### Embodiment 6

Preparation of Ti—Sb₂Te₃ Phase-Change Memory Materials Doped with Ti with Percentage Contents of Ti Atom of 6%, 8% and 10% Respectively, and an Sb₂Te₃ Phase-Change Memory Material without being Doped with Ti

In this embodiment, the Ti—Sb₂Te₃ phase-change memory material is obtained by co-sputtering an Sb₂Te₃ alloy target and a Ti target. Specific preparation conditions are: in the process of co-sputtering, an Ar gas with a purity of 99.999% is fed at the same time, the Sb₂Te₃ target adopts a radio frequency power supply, the Ti target adopts a direct current power supply, the power of the adopted radio frequency power supply is 25 W, and the power of the adopted direct current power supply is 15 W. The Sb₂Te₃ target is started before the Ti target power supply is turned on. The co-sputtering duration may be controlled according to the thickness of a film that undergoes phase change. In this embodiment, the Sb₂Te₃ phase-change memory material is obtained by sputtering an Sb₂Te₃ alloy target.

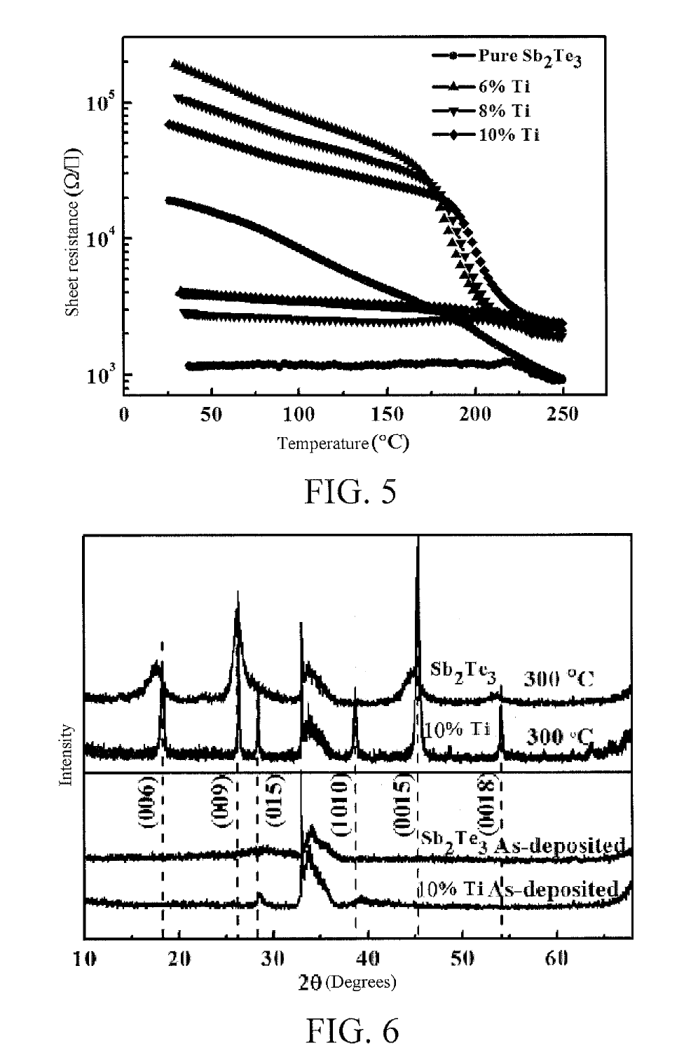

Tests of the Ti—Sb₂Te₃ phase-change memory material doped with Ti and the Sb₂Te₃ phase-change memory material without being doped with Ti that are obtained in this embodiment are performed, and results are shown in FIG. 5 to FIG. 8.

FIG. 5 shows temperature-resistance curves of a pure Sb₂Te₃ film and Ti—Sb₂Te₃ films doped with Ti of different contents at a heating rate of 10° C./min. According to FIG. 5, the initial resistance of pure Sb₂Te₃ is very low, because deposited Sb₂Te₃ has been partially crystallized. It can be seen from a crystallization temperature that, the higher the Ti content is, the higher the crystallization temperature is. The crystallization temperatures of Ti—Sb₂Te₃ films doped with 6% Ti, 8% Ti, and 10% Ti are 176° C., 185° C., and 194° C. respectively. In view of amorphous state resistance, when being doped with 6% Ti, the resistance in the amorphous state is an order of magnitude higher than that of pure Sb₂Te₃, and the amorphous state resistance when being doped with 8% and 10% Ti is lower than that when being doped with 6% Ti. As the content of the doped Ti increases, the high-resistance-to-low-resistance ratio increases and then decreases. However, the Ti—Sb₂Te₃ films doped with 6% Ti, 8% Ti, and 10% Ti all have a significantly improved thermal stability.

As shown in FIG. 6, deposited pure Sb₂Te₃ already has a diffraction peak, which proves that the deposited pure Sb₂Te₃ has been partially crystallized. The Ti—Sb₂Te₃ film doped with 10% Ti does not have any diffraction peak, and is in the amorphous state. Therefore, it can be known that the crystallization temperature of the Ti—Sb₂Te₃ film doped with Ti really increases. It can be known from a comparison result between XRD of pure Sb₂Te₃ and that of Ti—Sb₂Te₃ doped with 10% Ti that are annealed at 300° C. that, the two crystals have the same diffraction peak, so the crystal structure of Ti—Sb₂Te₃ doped with Ti is not changed, that is, phase separation does not occur. However, the intensity of the diffraction peak of Ti—Sb₂Te₃ doped with Ti decreases, indicating that after being doped, gains become smaller.

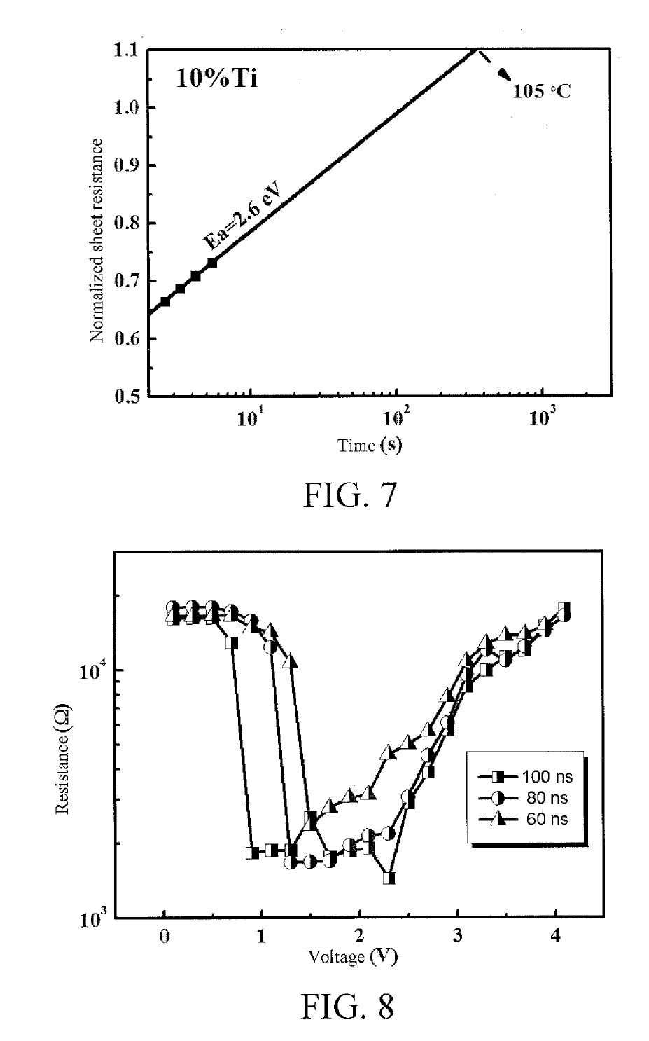

As shown in FIG. 7, according to the Arrhenius equation, it can be deduced that the temperature corresponding to the retention time of Ti—Sb₂Te₃ doped with 10% Ti is 105° C., which is 20° C. higher than that of GST (85° C.). The requirement of consumer electronics for retention is ensuring storage at 80° C. for 10 years, so Ti—Sb₂Te₃ doped with 10% Ti meets the requirement.

FIG. 8 shows resistance-voltage curves of a phase-change memory device based on a Ti—Sb₂Te₃ phase-change material doped with 10% Ti. It can be seen from FIG. 4 that, at 100 ns, voltages required for Set and Reset are 1 V and 3.3 V respectively. After pulse width decreases, Set and Reset operations can still be tested, but the voltage required for the Set operation increases. Therefore, the phase-change memory device based on the Ti—Sb₂Te₃ phase-change material doped with 10% Ti has a high crystallization rate, and can reversibly change between the amorphous state and the crystalline state on the order of nanosecond.

### Embodiment 7

Preparation of Ti—Sb₂Te₃ Phase-Change Memory Materials Doped with Ti of a Percentage Content of Ti Atom of 2%

In this embodiment, the Ti—Sb₂Te₃ phase-change memory material is obtained by co-sputtering an Sb₂Te₃ alloy target and a Ti target. Specific preparation conditions are: in the process of co-sputtering, an Ar gas with a purity of 99.999% is fed at the same time, the Sb₂Te₃ target adopts a radio frequency power supply, the Ti target adopts a direct current power supply, the power of the adopted radio frequency power supply is 25 W, and the power of the adopted direct current power supply is 15 W. The Sb₂Te₃ target is started before the Ti target power supply is turned on. The co-sputtering duration may be controlled according to the thickness of a film that undergoes phase change. In this embodiment, the Sb₂Te₃ phase-change memory material is obtained by sputtering an Sb₂Te₃ alloy target.

Tests of the Ti—Sb₂Te₃ phase-change memory material doped with Ti and obtained in this embodiment are performed, and results are as follows.

In the Ti—Sb₂Te₃ phase-change memory material doped with 2% Ti, Ti atoms replace Sb atoms, and phase separation does not occur.

In the Ti—Sb₂Te₃ phase-change memory material doped with 2% Ti, the resistivity is reversibly changed under the action of an electric pulse.

In the Ti—Sb₂Te₃ phase-change memory material doped with 2% Ti, the optical reflectivity is reversibly changed under the action of a laser pulse.

The amorphous state resistance of the Ti—Sb₂Te₃ phase-change memory material doped with 2% Ti is an order of magnitude higher than that of pure Sb₂Te₃.

The crystallization temperature of the Ti—Sb₂Te₃ phase-change memory material doped with 2% Ti is significantly risen, the thermal stability is significantly improved, and the data retention is enhanced.

The melting point and the thermal conductivity of the Ti—Sb₂Te₃ phase-change memory material doped with 2% Ti are lowered.

It can be known from a comparison result between XRD of Ti—Sb₂Te₃ doped with 2% Ti and that of pure Sb₂Te₃ that are annealed at 300° C., the two crystals have the same diffraction peak, so the crystal structure of the Ti—Sb₂Te₃ doped with Ti is not changed, that is, phase separation does not occur. However, the intensity of the diffraction peak of Ti—Sb₂Te₃ doped with Ti decreases, indicating that after being doped, gains become smaller.

It can be known from the resistance-voltage curves of the phase-change memory device based on the Ti—Sb₂Te₃ phase-change material doped with 2% Ti that, the phase-change memory device based on the Ti—Sb₂Te₃ phase-change material doped with 2% Ti has a higher crystallization rate, and can reversibly change between the amorphous state and the crystalline state on the order of nanosecond.

### Embodiment 8

Preparation of Ti—Sb₂Te₃ Phase-Change Memory Materials Doped with Ti of a Percentage Content of Ti Atom of 20%

In this embodiment, the Ti—Sb₂Te₃ phase-change memory material is obtained by co-sputtering an Sb₂Te₃ alloy target and a Ti target. Specific preparation conditions are: in the process of co-sputtering, an Ar gas with a purity of 99.999% is fed at the same time, the Sb₂Te₃ target adopts a radio frequency power supply, the Ti target adopts a direct current power supply, the power of the adopted radio frequency power supply is 25 W, and the power of the adopted direct current power supply is 15 W. The Sb₂Te₃ target is started before the Ti target power supply is turned on. The co-sputtering duration may be controlled according to the thickness of a film that undergoes phase change. In this embodiment, the Sb₂Te₃ phase-change memory material is obtained by sputtering an Sb₂Te₃ alloy target.

Tests of the Ti—Sb₂Te₃ phase-change memory material doped with Ti and obtained in this embodiment are performed, and results are as follows.

In the Ti—Sb₂Te₃ phase-change memory material doped with 20% Ti, Ti atoms replace Sb atoms, and phase separation does not occur.

In the Ti—Sb₂Te₃ phase-change memory material doped with 20% Ti, the resistivity is reversibly changed under the action of an electric pulse.

In the Ti—Sb₂Te₃ phase-change memory material doped with 20% Ti, the optical reflectivity is reversibly changed under the action of a laser pulse.

The crystallization temperature of the Ti—Sb₂Te₃ phase-change memory material doped with 20% Ti is significantly risen, the thermal stability is significantly improved, and the data retention is enhanced.

The melting point and the thermal conductivity of the Ti—Sb₂Te₃ phase-change memory material doped with 20% Ti are lowered.

It can be known from a comparison result between XRD of annealing of Ti—Sb₂Te₃ doped with 20% Ti and that of annealing of pure Sb₂Te₃ at 300° C. that, the two crystals have the same diffraction peak, so the crystal structure of the Ti—Sb₂Te₃ doped with Ti is not changed, that is, phase separation does not occur. However, the intensity of the diffraction peak of Ti—Sb₂Te₃ doped with Ti decreases, indicating that after being doped, gains become smaller.

According to the Arrhenius equation, it can be deduced that the temperature corresponding to the retention time of Ti—Sb₂Te₃ doped with 20% Ti is higher than that of GST (85° C.). The requirement of consumer electronics for retention is ensuring storage at 80° C. for 10 years, so Ti—Sb₂Te₃ doped with 20% Ti meets the requirement.

It can be known from the resistance-voltage curves of the phase-change memory device based on the Ti—Sb₂Te₃ phase-change material doped with 20% Ti that, the phase-change memory device based on the Ti—Sb₂Te₃ phase-change material doped with 20% Ti has a higher crystallization rate, and can reversibly change between the amorphous state and the crystalline state on the order of nanosecond.

Descriptions and applications of the embodiments of the present invention are illustrative, and are not intended to limit the scope of the present invention to the aforementioned embodiments. Variations and modifications may be made to the embodiments disclosed herein. For persons of ordinary skill in the art, various equivalent components for replacement performed on the embodiments are well-known. It should be understood by persons skilled in the art that the present invention may be implemented in other forms, structures, arrangements and scales and by using other substrates, materials, and components without departing from the spirit or essence of the present invention. Other variations and modifications may be made to the embodiments disclosed herein without departing from the scope and spirit of the present invention.

1. An Sb—Te—Ti phase-change memory material for a phase-change memory, formed by doping an Sb—Te phase-change memory material with Ti, and having a chemical formula of SbₓTe_{y}Ti_{100-x-y}, wherein 0<x<80, and 0<y<100-x.

2. The Sb—Te—Ti phase-change memory material for a phase-change memory as in claim 1, wherein x satisfies 45≦x≦72, and y satisfies 5≦y≦45.

3. The Sb—Te—Ti phase-change memory material for a phase-change memory as in claim 1, wherein a resistivity of the Sb—Te—Ti phase-change memory material is reversibly changed under the action of an electric pulse.

4. The Sb—Te—Ti phase-change memory material for a phase-change memory as in claim 1, wherein an optical reflectivity of the Sb—Te—Ti phase-change memory material is reversibly changed under the action of a laser pulse.

5. The Sb—Te—Ti phase-change memory material for a phase-change memory as in claim 1, wherein the Sb—Te—Ti phase-change memory material is an Sb—Te—Ti phase-change thin-film material.

6. The Sb—Te—Ti phase-change memory material for a phase-change memory as in claim 1, wherein the Sb—Te phase-change memory material is an Sb₂Te₃ phase-change memory material, the Sb—Te—Ti phase-change memory material obtained by doping the Sb₂Te₃ phase-change memory material with Ti is a Ti—Sb₂Te₃ phase-change memory material, and in the chemical formula SbₓTe_{y}Ti_{100-x-y}, y=3/2x, and a percentage content of Ti atom is lower than 50%.

7. The Sb—Te—Ti phase-change memory material for a phase-change memory as in claim 6, wherein in the Ti—Sb₂Te₃ phase-change memory material, the percentage content of Ti atom is in the range of 2% and 20%.

8. The Sb—Te—Ti phase-change memory material for a phase-change memory as in claim 6, wherein in the Ti—Sb₂Te₃ phase-change memory material, Ti atoms replace Sb atoms, and phase separation does not occur.

9. The Sb—Te—Ti phase-change memory material for a phase-change memory as in claim 6, wherein in the Ti—Sb₂Te₃ phase-change memory material, as the content of the doped Ti increases, an amorphous state resistance of the Ti—Sb₂Te₃ phase-change memory material increases and then decreases.

10. A preparation method of the Sb—Te—Ti phase-change memory material for a phase-change memory as in claim 1, comprising: according to a ratio of Sb to Te in a chemical formula SbₓTe_{y}Ti_{100-x-y}, co-sputtering an SbₓTe_{y} alloy target and a Ti target to obtain the Sb—Te—Ti phase-change memory material.

11. The preparation method as in claim 10, wherein sputtering conditions of the co-sputtering are: in the process of co-sputtering, an Ar gas with a purity of 99.999% is fed at the same time, the SbₓTe_{y} target adopts a radio frequency power supply, and the Ti target adopts a direct current power supply.

12. The preparation method as in claim 11, wherein during co-sputtering, the SbₓTe_{y} alloy target is started before the Ti target power supply is turned on.

13. The preparation method as in claim 11, wherein power of the radio frequency power supply is 25 W, power of the direct current power supply is 15 W, and a co-sputtering duration is 15 to 50 minutes.

14. The preparation method as in claim 10, wherein the obtained Sb—Te—Ti phase-change memory material is a phase-change thin-film material, and the thickness of the film is in the range of 100 nm to 250 nm.

15. A phase-change memory unit based on the Sb—Te—Ti phase-change memory material as in claim 1.

16. The phase-change memory unit as in claim 15, wherein the Sb—Te—Ti phase-change memory material is a Ti—Sb₂Te₃ phase-change memory material, as the content of doped Ti increases, a Reset voltage of the phase-change memory unit increases; as the content of doped Ti increases, a high resistance of the phase-change memory unit increases and then decreases, and a high-resistance-to-low-resistance ratio also increases and then decreases.

17. A preparation method of the Sb—Te—Ti phase-change memory material for a phase-change memory as in claim 6, comprising: according to a ratio of Sb to Te in a chemical formula SbₓTe_{y}Ti_{100-x-y}, co-sputtering an SbₓTe_{y} alloy target and a Ti target to obtain the Sb—Te—Ti phase-change memory material.

18. A preparation method of the Sb—Te—Ti phase-change memory material for a phase-change memory as in claim 9, comprising: according to a ratio of Sb to Te in a chemical formula SbₓTe_{y}Ti_{100-x-y}, co-sputtering an SbₓTe_{y} alloy target and a Ti target to obtain the Sb—Te—Ti phase-change memory material.

19. A phase-change memory unit based on the Sb—Te—Ti phase-change memory material as in claim 6.

20. A phase-change memory unit based on the Sb—Te—Ti phase-change memory material as in claim 9.
